(19) United States
(12) Patent Application Publication
(10) Pub. No.: US 2013/0256790 A1
(43) Pub. Date: Oct. 3, 2013

(54) SEMICONDUCTOR DEVICE AND METHOD FOR MANUFACTURING THE SAME

(71) Applicant: SK HYNIX INC., Icheon (KR)

(72) Inventor: Chi Hwan JANG, Icheon (KR)

(73) Assignee: SK HYNIX INC., Icheon (KR)

(21) Appl. No.: 13/719,115

(22) Filed: Dec. 18, 2012

(30) Foreign Application Priority Data
Apr. 2, 2012 (KR) 10-2012-0033821

(51) Int. Cl. H01L 29/423; H01L 29/40

(52) U.S. Cl. CPC H01L 29/4236; H01L 29/401
USPC 257/331; 438/586

(57) ABSTRACT

A semiconductor device includes buried gates formed in a semiconductor substrate in which active regions and an isolation layer are defined. A bit line is coupled to an active region between the buried gates and disposed to cross the buried gates. In the 6F² structure, characteristics of the semiconductor device are improved by applying omitting a bit line contact plug.

### CROSS-REFERENCES TO RELATED APPLICATION

The present application claims priority to Korean patent application number 10-2012-0033821, filed on 2 Apr. 2012, which is incorporated by reference in its entirety.

### BACKGROUND OF THE INVENTION

The present invention relates to a semiconductor device and a method for manufacturing the same.

Semiconductor memory devices include a plurality of unit cells comprised of a capacitor and a transistor. The capacitor temporarily stores data, and the transistor transfers data between a bit line and the capacitor based on a semiconductor property in which electric conductivity changes according to environment. The transistor includes a gate, a source, and a drain, and charges are transferred between the source and drain according to a control signal input to the gate. The movement of charges between the source and drain occurs through a channel region.

The conventional transistor is formed by forming a gate on the semiconductor substrate and doping impurities in the semiconductor substrate at both sides of the gate to form the source and drain. As data storage capacity and integration of the semiconductor memory device have increased, demand has increased to fabricate each unit cell more finely. However, as the design rule of the capacitor and transistor included in the unit cell is reduced, the length of the channel of the cell transistor is reduced. As a result, short channel effects and drain induced barrier lowering (DIBL) may occur, and thus operational reliability is degraded. The phenomena generated by the reduction in the channel length can be overcome when a threshold voltage of the transistor is maintained to perform a normal operation.

In addition, as the channel length of the transistor is shortened, the concentration of impurities doped to form the source and drain is generally increased. The increase in the doping concentration, due to reduction in the design rule to below 100 nm, causes an increase in the electric field in a storage node (SN) junction, thus causing other issues, such as degradation of refresh characteristics.

To overcome these issues, a three-dimensional (3D) channel structure has been used to ensure a longer channel in the vertical direction. The 3D channel structure may maintain the channel length of the cell transistor even when the design rule is reduced. Since the doping concentration can be reduced by the longer vertical length of the channel even when the channel width in the horizontal direction is shortened, the degradation of refresh characteristics can be prevented.

Further, as the semiconductor device becomes more highly integrated, the distance between the gate coupled to the cell transistor and the bit line is narrowed. Thus, parasitic capacitance is increased, degrading an operation margin of a sense amplifier, which amplifies data transferred through the bit line. This has a disastrous effect on the operational reliability of the semiconductor device.

To solve the issue, a buried gate structure, in which the gate is formed not on the semiconductor substrate, but in a recess of the semiconductor substrate, has been suggested to reduce the parasitic capacitance between the gate and the bit line. The buried gate structure is formed by forming a conductive material in the recess formed in the semiconductor substrate, and forming an insulating layer to cover the conductive material so that the gate is buried in the semiconductor substrate. Since the bit line and the bit line contact plug is formed on the surface of the semiconductor substrate, and the gate, the source and drain are formed in the semiconductor substrate, the electrical isolation between the gate and a bit line or a bit line contact plug can be obtained.

### BRIEF SUMMARY OF INVENTION

According to one aspect of an embodiment, there is provided a semiconductor device including a bit line, and a method for manufacturing the same. The semiconductor device may include: a plurality of buried gates formed in a semiconductor substrate, the semiconductor substrate including active regions and an isolation layer; a bit line being coupled to an active region between the buried gates, the bit line being disposed to cross the buried gates.

The buried gates are disposed so that two buried gates pass through one active region.

The semiconductor device may further include a sealing layer formed over each of the buried gates.

The sealing layer may include a low-k dielectric material such as a material.

The bit line may pass through central portions of the active regions and be directly coupled to the semiconductor substrate.

The bit line may be formed in a line type.

The bit line may be formed in a stacked structure including a barrier metal layer, a bit line conductive material, and a bit line hard mask layer.

The semiconductor device may further include storage node contact plugs coupled to the semiconductor substrate at opposing ends of the active region.

The semiconductor device may have a 6F² structure.

According to another aspect of an embodiment, there is provided a method for manufacturing a semiconductor device. The method may include: forming a buried gate in a semiconductor substrate, the semiconductor substrate including an active region and isolation layer; and forming a bit line to be coupled to the active region between the buried gates, the bit line crossing the buried gates.

The forming a buried gate may include etching the semiconductor substrate to form a recess, and burying a gate conductive material in a lower portion of the recess.

The method may further include forming a sealing layer over the gate conductive material.

The sealing layer may include a low-k dielectric material.

The forming a sealing layer may include entirely forming a sealing material on the semiconductor substrate including the recess in which the gate conductive material is formed, and etching the sealing material through a planarization process to expose portions of the semiconductor substrate.

The forming a sealing layer may include entirely forming a sealing material over an entire surface of the semiconductor substrate including the recess in which the gate conductive material is formed, and etching the sealing layer to expose the semiconductor substrate in a central portion of the active region.

The forming a bit line may include sequentially forming a barrier metal layer, a bit line conductive material, and a bit line hard mask layer on an entire surface of the semiconductor substrate, including the sealing layer, and patterning the bit line hard mask layer, the bit line conductive material, and the barrier metal layer.

The forming a bit line may include forming the bit line in a line shape directly coupled to a central portion of the active region.

The method may further, after the forming a bit line, include forming an insulating layer on an entire surface of the semiconductor substrate including the bit line, etching the insulating layer to form storage node contact hole disposed at the opposing ends of the active region, and burying a conductive material in the storage node contact hole to form a storage node contact plug.

The semiconductor device may be formed in a 6F² structure.

These and other features, aspects, and embodiments are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 illustrates a plan view and a cross-sectional view of a semiconductor device according to an embodiment of the present invention;

FIGS. 2A to 2G are cross-sectional views illustrating a method for manufacturing a semiconductor device according to an embodiment of the present invention; and

FIGS. 3A to 3E are cross-sectional views illustrating a method for manufacturing a semiconductor device according to another embodiment of the present invention.

### DETAILED DESCRIPTION

Hereinafter, embodiments will be described in greater detail with reference to the accompanying drawings.

Embodiments are described herein with reference to illustrations that are schematic illustrations of embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

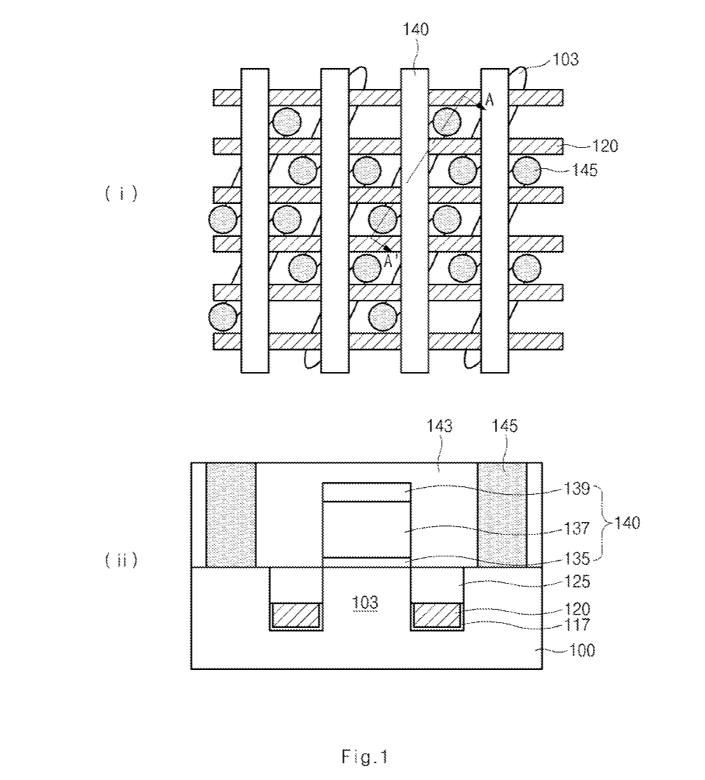

FIG. 1 (i)-(ii) are drawings illustrating a plan view and a cross-sectional view of structures according to embodiments. FIG. 1 (i) shows a plan view of the semiconductor device and FIG. 1 (ii) shows a cross-sectional view of the semiconductor device taken along line A-A′.

Referring to FIG. 1, an active region 103 and a device isolation layer (not shown) are formed in a semiconductor substrate 100. A plurality of gates 120 are formed in the active region 103 and a gate insulating layer 117 is further formed on an outer circumference of each of the gates 120. In an embodiment, the gates 120 are buried gates. Two gates 120 may be formed in one active region 103. The gate 120 may have a structure in which the gate 120 is entirely buried by a sealing layer 125 formed on the gate 120.

A bit line 140, which passes through the active region 103, extends in a direction perpendicular to the gate 120. The bit line 140 is formed of a stacked structure including a barrier metal layer 135, a bit line conductive material 137, and a bit line hard mask layer 139. The bit line 140 is formed to be directly coupled to the active region 103 without a separate bit line contact plug. An insulating layer 143 is formed over an entire surface of the semiconductor substrate 100, including the bit line 140. A storage node contact plug 145, which penetrates the insulating layer 143, is coupled to an end of the active region 103 on either side of the bit line 140.

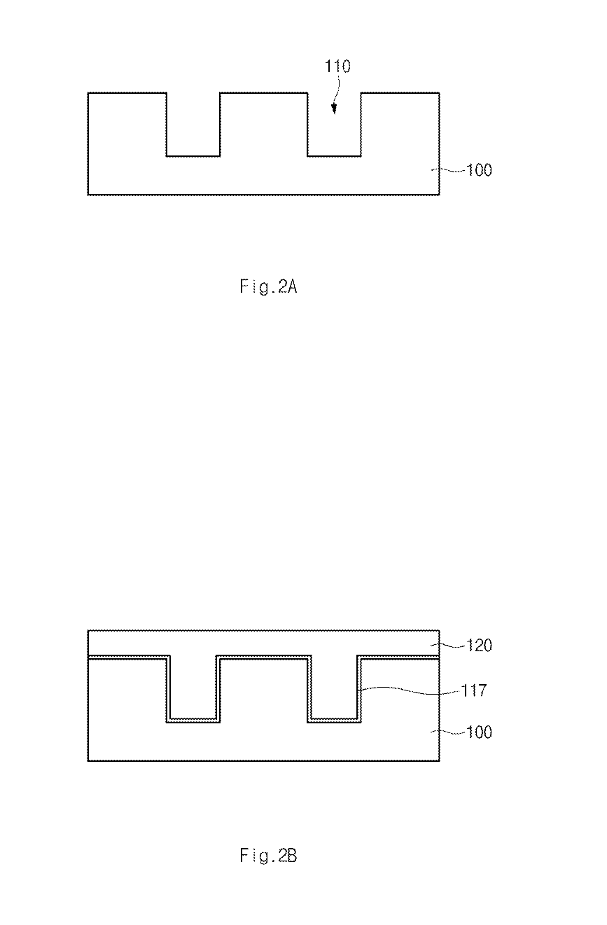

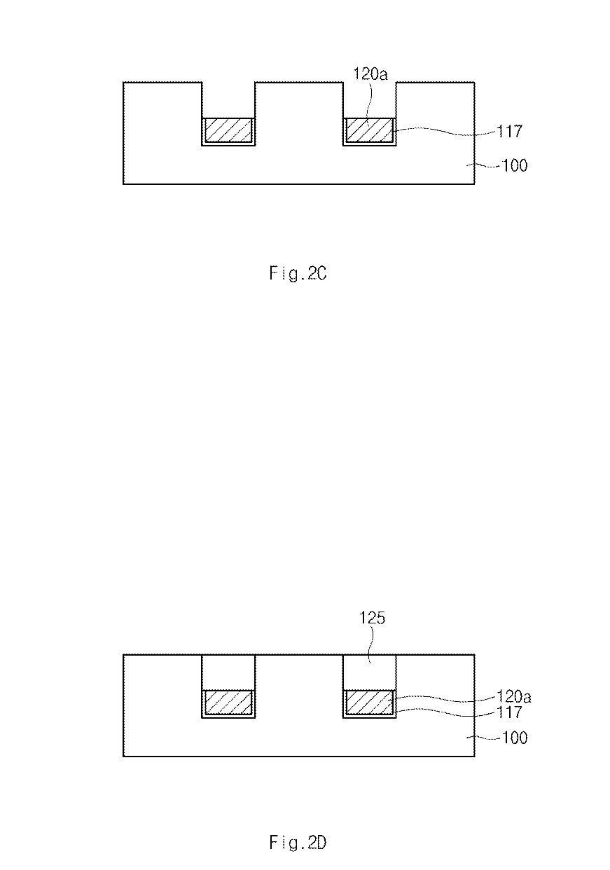

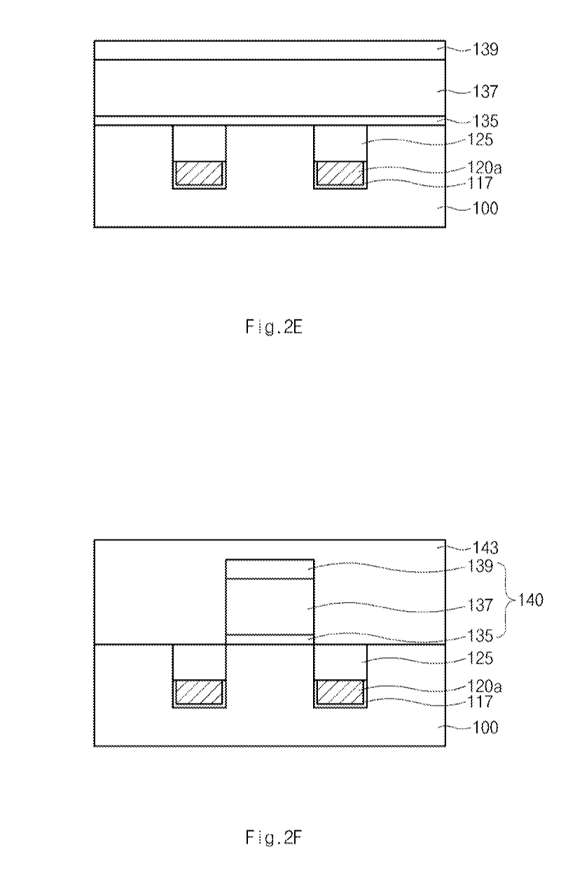

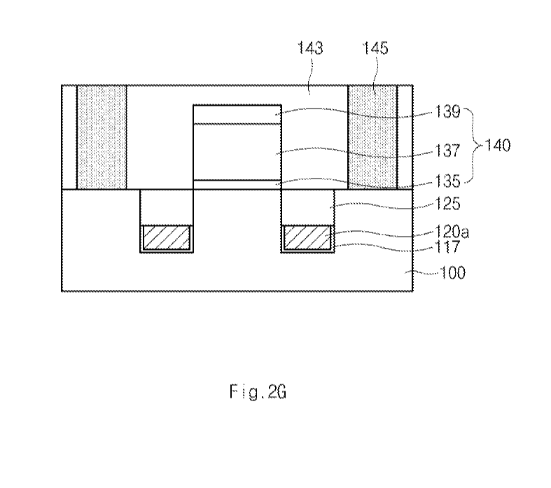

FIGS. 2A to 2G are cross-sectional views illustrating a method for manufacturing a semiconductor device according to an

embodiment of the present invention.

First, referring to FIG. 2A, a mask pattern (not shown) defining a gate region is formed on a semiconductor substrate 100 that includes an active region, and the semiconductor substrate 100 is etched using the mask pattern as an etch mask to form a recess 110. In an embodiment, the process of etching the semiconductor substrate 100 may be performed through a wet etch process or a dry etch process. Then, the mask pattern (not shown) is removed.

Referring to FIG. 2B, a gate insulating layer 117 is formed over the semiconductor substrate, including an inner wall of the recess 110. The gate insulating layer 117 may be formed through a chemical vapor deposition (CVD) method or using a furnace. A barrier metal layer (not shown) may be further formed on the gate insulating layer 117 to suppress a reaction between a gate conductive material to be formed in a subsequent process and the gate insulating layer 117. The barrier metal layer (not shown) may be formed through a CVD method, a metal-organic chemical vapor deposition (MOCVD) method, or an atomic layer deposition (ALD) method.

The barrier metal layer (not shown) may serve as a diffusion prevention layer. That is, the barrier metal layer (not shown) may prevent the gate conductive material from being diffused into the gate insulating layer 117. Thus, the barrier metal layer (not shown) may include an oxide-based material such as molybdenum oxide (MoOx), zirconium oxide (ZrOx), tantalum oxide (TaOx), titanium oxide (TiOx), ruthenium oxide (RuOx), or chromium oxide (CrOx) or a nitride-based material such as tungsten nitride (WN), WSiNx, molybdenum nitride (MoNx), zirconium nitride (ZrNx), tantalum nitride (TaNx), titanium nitride (TiNx), ruthenium nitride (RuNx), or chromium oxide (CrNx). The barrier metal layer (not shown) may be formed by forming a high-k dielectric material, such as zirconium (Zr) or hafnium (Hf), and performing any one of oxidization, carbonization, and nitration so that the diffusion barrier layer and the gate insulating layer 117 are further solidified.

Next, a gate conductive material 120 is formed over an entire surface of the semiconductor substrate 100, including the gate insulating layer 117. The gate conductive material 120 may include any of tungsten (W), copper (Cu), tantalum (Ta), and titanium (Ti), or a combination thereof. The gate conductive material 120 may be formed through a physical vapor deposition (PVD) method, a CVD method, a MOCVD method, or an ALD method.

Referring to FIG. 2C, a planarization process is performed on the gate conductive material 120 until the semiconductor substrate 100 is exposed. Then the gate conductive material 120 in the recess 110 is further etched so that the gate conductive material 120 remains only in a lower portion of the recess 110. The remaining gate conductive material forms the buried gate 120a.

Referring to FIG. 2D, a sealing layer 125 is formed on an entire surface of the semiconductor substrate 100, including the recess 110 in which the buried gate 120a is formed. A planarization process is performed on the sealing layer 125 until the semiconductor substrate 100 is exposed and the sealing layer 125 remains on the buried gate 120a within the recess 110. The sealing layer 125 serves to completely isolate adjacent buried gates 120a. The sealing layer 125 may be formed of a nitride layer.

Referring to FIG. 2E, a barrier metal layer 135 is formed over an entire surface of the semiconductor substrate 100, including the sealing layer 125. Subsequently, a bit line conductive material 137 and a bit line hard mask layer 139 are formed on the barrier metal layer 135. The bit line conductive material 137 may be formed through a CVD method, a MOCVD method, or an ALD method.

The barrier metal layer 135 may serve as a diffusion prevention layer. That is, the barrier metal layer 135 may prevent the bit line conductive material 137 from being diffused below the bit line. Thus, the barrier metal layer 135 may include an oxide-based material such as MoOx, ZrOx, TaOx, TiOx, RuOx, or CrOx, or a nitride-based material such as WN, WSiNx, MoNx, ZrNx, TaNx, TiNx, RuNx, or CrNx. Further, the bite conductive material 137 may be formed of any of tungsten (W), copper (Cu), tantalum (Ta), and titanium (Ti), or a combination thereof. The bit line hard mask layer 139 may be formed of a nitride layer.

Referring to FIG. 2F, the barrier metal layer 135, bit line conductive material 137, and the bit line hard mask layer 139 are patterned to form a bit line 140. The bit line 140 may be formed to extend in a direction perpendicular to the buried gate 120a. Further, the bit line 140 may be formed to be in direct coupled to the semiconductor substrate 100 in a bit line contact region, without a bit line contact plug provided between the semiconductor substrate 100 and the bit line 140.

In an embodiment, a spacer (not shown) is formed on a sidewall of the bit line 140. The spacer (not shown) serves to insulate the bit line from a storage node contact plug to be formed in a subsequent process. The spacer (not shown) may be formed of any of an oxide layer, a nitride layer, and a carbon layer, or a combination thereof.

Next, an insulating layer 143 is formed over an entire surface of the semiconductor substrate, including the bit line 140, and is then planarized. In an embodiment, the insulating layer 143 may include a nitride layer, an oxide layer, or a combination thereof. Further, in an embodiment, the insulating layer 143 may include a low-k dielectric material such as a material containing carbon.

Referring to FIG. 2G, portions of the insulating layer 143 are etched to form storage node contact holes that expose the semiconductor substrate 100 in storage node contact regions. In an embodiment, a spacer (not shown) is formed on an inner sidewall of each of the storage node contact holes, and a conductive material is buried within the storage node contact holes to form storage node contact plugs 145. The storage node contact plugs 145 may be formed by using a metal material or an element of Group IV. When the storage node contact plug 145 is formed using the metal material, the storage node contact plug 145 may be formed of an oxide-based material such as MoOx, ZrOx, TaOx, TiOx, RuOx, or CrOx or a nitride-based material such as WN, WSiNx, MoNx, ZrNx, TaNx, TiNx, RuNx, or CrNx.

As described above, according to an embodiment of the present invention, the bit line contact plug is omitted and the bit line 140 is in direct contact with the semiconductor substrate 100, so that the contact resistance between the bit line 140 and the semiconductor substrate 100 can be minimized. In other words, in an embodiment of the present invention, unlike the conventional art, no contact plug is disposed between the bit line 140 and the semiconductor substrate 100. Since the bit line contact plug can be omitted, the distance from the surface of the semiconductor substrate 100 to a top of the bit line 140 is lowered, thus a height of the storage node contact plug 145 is lowered. Therefore, the resistance of the storage node contact plug 145 is minimized. As the contact resistance between the bit line 140 and the semiconductor substrate 100, and the resistance of the storage node contact plug 145 are minimized, operation speed of the semiconductor memory device is increased, and the device consumes less power.

By omitting the bit line contact plug, a failure generated around the bit line contact plug can be suppressed. Instead of implementing a bit line contact plug formed in a recess, the present invention implements a line type bit line. Thus, a contact area between the active region and the bit line is increased to reduce the contact resistance.

Further, by omitting the process of forming the bit line contact plug, the fabrication process is simplified. In addition, a step difference between a cell area and a peripheral circuit area is reduced.

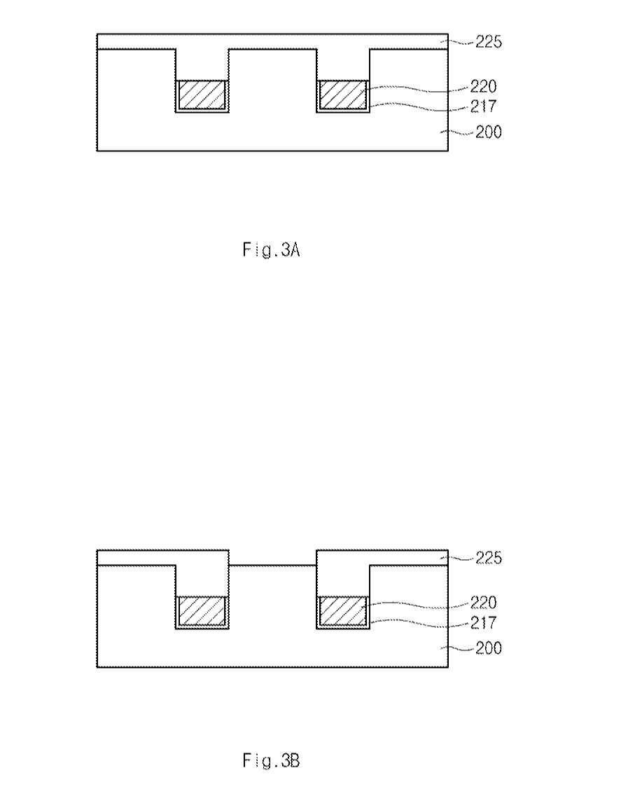

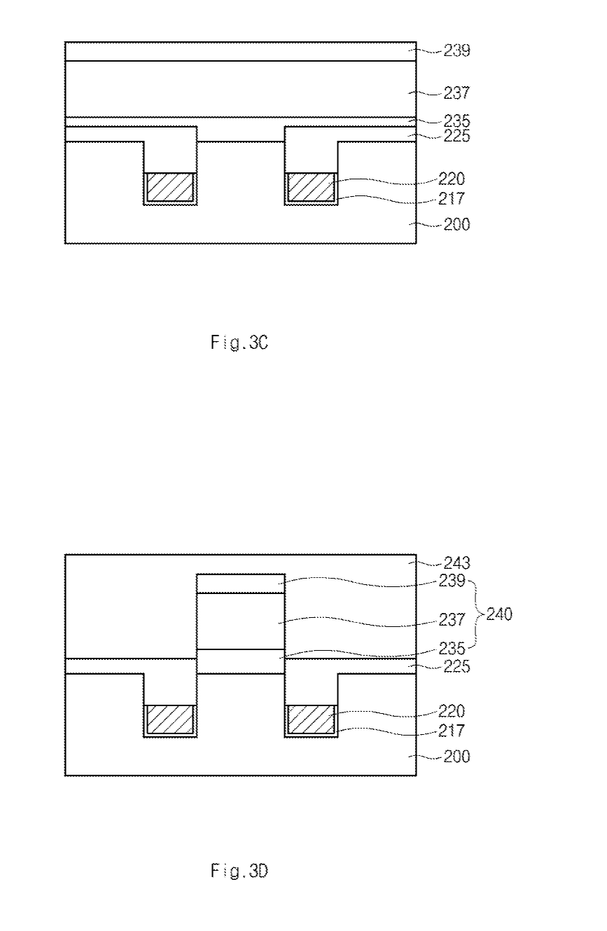

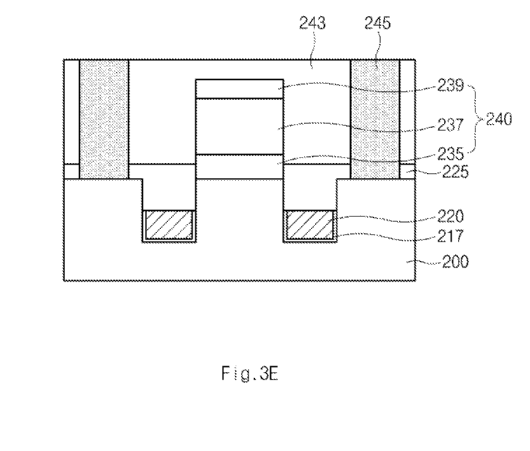

FIGS. 3A to 3E are cross-sectional views illustrating a method for manufacturing a semiconductor device according to another exemplary embodiment of the present invention.

First, referring to FIG. 3A, a mask pattern (not shown) defining a gate region is formed on a semiconductor substrate 200 and the semiconductor substrate 200 is etched using the mask pattern as an etch mask to form a recess. In an embodiment, the process of etching the semiconductor substrate 200 may be performed through a wet etch process or a dry etch process. Then, the mask pattern (not shown) is removed. A gate insulating layer 217 is formed on an inner surface of the recess, and a gate conductive material is formed over the insulating layer 217. A planarization process is performed on the gate conductive material until the semiconductor substrate 200 is exposed. The gate conductive material in the recess is further etched so that it remains only in a lower portion of the recess. The remaining gate conductive material serves as a buried gate 220. Subsequently, a sealing layer 225 is formed over an entire surface of the semiconductor substrate 200, including the recess in which the buried gate 220 is formed. In an embodiment, the structures illustrated in FIG. 3A may be formed by the same processes illustrated in FIGS. 2A to 2D using the same or similar methods and materials.

Referring to FIG. 3B, a mask pattern (not shown) opening a bit line contact region is formed on the sealing layer 225, and the sealing layer 225 is etched using the mask pattern (not shown) as an etch mask to expose the semiconductor substrate 200 in the bit line contact region. The sealing layer 225 remaining on the semiconductor substrate 200 serves to insulate the buried gates 220 from a bit line, and the buried gates 220 from a storage node contact plug. That is, the sealing layer 225 prevents the bit line, which is formed in a subsequent process, from being coupled to the active region coupled to the storage node contact plug formed in a subsequent process. The sealing layer 225 may be etched until the semiconductor substrate 200 is exposed in the bit line contact region. When the sealing layer 225 in the bit line contact region of the semiconductor substrate 200 is entirely removed, a process of forming an insulating layer (not shown) over the bit line contact region may be further performed.

Referring to FIG. 3C, a barrier metal layer 235, a bit line conductive material 237, and a bit line hard mask layer 239 are sequentially formed over an entire surface of the semiconductor substrate 200. The barrier metal layer 235, bit line contact plug 237, and bit line hard mask layer 239 may be formed using the same or similar materials and processes as those described in connection with FIG. 2E.

Referring to FIG. 3D, the barrier metal layer 235, bit line conductive material 237, and the bit line hard mask layer 239 are patterned to form a bit line 240. The bit line 240 may be formed to be directly connected to the semiconductor substrate 200 in the bit line contact region, without a bit line contact plug provided between the substrate 200 and the bit line 240. The bit line 240 may extend in a direction perpendicular to the buried gate 220. In an embodiment, a spacer (not shown) is formed on a sidewall of the bit line 240. The spacer (not shown) serves to insulate the bit line from the storage node contact plug to be formed in a subsequent process. An insulating layer 243 is formed over an entire surface of the semiconductor substrate, including the bit line 240, and is then planarized.

Referring to FIG. 3E, portions of the insulating layer 243 and sealing layer 225 are etched to form storage node contact holes exposing the semiconductor substrate 200 in storage node contact regions. In an embodiment, a spacer (not shown) is formed on an inner wall of each of the storage node contact holes, and a conductive material is buried in the storage node contact holes to form a storage node contact plugs 245.

As described above, in accordance with an embodiment of the present invention, formation of a bit line contact plug may be omitted, and the bit line 240 is formed so that the contact resistance between the bit line 240 and the semiconductor substrate 200 can be minimized. Since the bit line contact plug is not formed, the distance from the surface of the semiconductor substrate 200 to a top of the bit line 240 is reduced. Thus, a height of the storage not contact plug 245 is lowered. Therefore, the resistance of the storage node contact plug 245 is minimized. As the contact resistance between the bit line 240 and the semiconductor substrate 200, and the resistance of the storage node contact plug 245 are minimized, operation speed of the semiconductor device is increased, and the device consumes less power.

By omitting the bit line contact plug, a failure generated around the bit line contact plug can be suppressed. In contrast to a conventional bit line contact plug, formed in a recess, in accordance with an embodiment of the present invention, a line type bit line is used. Thus a contact area between the active region and the bit line is increased to reduce the contact resistance.

Further, by omitting the process of forming the bit line contact plug, the fabrication process is simplified. In addition, a step difference between a cell area and a peripheral circuit area is reduced.

The above embodiments of the present invention are illustrative and not limitative. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A semiconductor device, comprising:
a plurality of buried gates formed in a semiconductor substrate, the semiconductor substrate including active regions and an isolation layer; and
a bit line coupled to an active region between the buried gates, the bit line being arranged to cross the buried gates.

2. The semiconductor device of claim 1, wherein the buried gates are disposed so that two buried gates pass through one active region.

3. The semiconductor device of claim 1, further comprising a sealing layer formed over each of the buried gates.

4. The semiconductor device of claim 3, wherein the sealing layer includes a low-k dielectric material.

5. The semiconductor device of claim 1, wherein the bit line passes through a central portion of the active region and is in direct contact with the semiconductor substrate.

6. The semiconductor device of claim 1, wherein bit line is a line type bit line.

7. The semiconductor device of claim 1, wherein the bit line has a stacked structure including a barrier metal layer, a bit line conductive material, and a bit line hard mask layer.

8. The semiconductor device of claim 1, further comprising storage node contact plugs coupled to the semiconductor substrate at opposing ends of the active region.

9. The semiconductor device of claim 1, wherein the semiconductor device has a 6F² structure.

10. A method for manufacturing a semiconductor device, the method comprising:
forming buried gates in a semiconductor substrate, the semiconductor substrate including an active region and an isolation layer; and
forming a bit line to be coupled to the active region between the buried gates, the bit line crossing the buried gates.

11. The method of claim 10, wherein the forming buried gates includes:
etching the semiconductor substrate to form recesses; and
burying a gate conductive material in lower portions of the recesses.

12. The method of claim 11, further comprising forming a sealing layer over the gate conductive material.

13. The method of claim 12, wherein the sealing layer includes a low-k dielectric material.

14. The method of claim 12, wherein forming the sealing layer includes:
forming a sealing material over an entire surface of the semiconductor substrate including the recesses in which the gate conductive material is formed; and
etching the sealing material through a planarization process to expose portions of the semiconductor substrate.

15. The method of claim 11, wherein forming the sealing layer includes:
forming a sealing material over an entire surface of the semiconductor substrate including the recesses in which the gate conductive material is formed; and
etching the sealing material to expose the semiconductor substrate in a central portion of the active region.

16. The method of claim 11, wherein forming the bit line includes:
sequentially forming a barrier metal layer, a bit line conductive material, and a bit line hard mask layer over an entire surface of the semiconductor substrate, including the sealing layer; and
patterning the bit line hard mask layer, the bit line conductive material, and the barrier metal layer.

17. The method of claim 10, wherein forming the bit line includes forming the bit line in a line shape, wherein the bit line is in direct contact with a central portion of the active region.

18. The method of claim 10, further comprising, after forming the bit line,
forming an insulating layer over an entire surface of the semiconductor substrate including the bit line;
etching the insulating layer to form storage node contact holes exposing opposing ends of the active region; and
burying a conductive material in the storage node contact holes to form storage node contact plugs.

19. The method of claim 10, wherein the semiconductor device has a 6F² structure.
